(19) United States
(12) Patent Application Publication
(10) Pub. No.: US 2025/0391768 A1
(43) Pub. Date: Dec. 25, 2025

(54) SEMICONDUCTOR DEVICE AND MANUFACTURING METHOD THEREFOR, AND DYNAMIC RANDOM ACCESS MEMORY

(71) Applicant: CXMT Corporation, Hefei City (CN)

(72) Inventors: Hao MENG, Hefei City (CN); Yi JIANG, Hefei City (CN); Daohuan FENG, Hefei City (CN)

(73) Assignee: CXMT Corporation, Hefei City (CN)

(21) Appl. No.: 18/963,428

(22) Filed: Nov. 27, 2024

Related U.S. Application Data
(63) Continuation of application No. PCT/CN2024/124340, filed on Oct. 12, 2024.

(30) Foreign Application Priority Data
Jun. 20, 2024 (CN) 202410806141.6

(51) Int. Cl. H01L 23/528; H10B 12/00; H10D 62/80

(52) U.S. Cl. CPC H01L 23/5283; H10B 12/488; H10D 62/875; H10B 12/482

(57) ABSTRACT

Provided are a semiconductor device and manufacturing method therefor, and a three-dimensional dynamic random access memory. The semiconductor device includes: a substrate; channel structures, arranged on the substrate along a first direction; bit lines, each arranged between one of the channel structures and the substrate and electrically connected to the channel structure, and extending along a second direction; and word lines, each arranged on at least one side of the channel structure and extending along a third direction, where the first direction intersects with the substrate, the second direction is parallel to the substrate, and the third direction is parallel to the substrate and intersects with the second direction; and the channel structure includes a filling material and an oxide semiconductor layer arranged on an outer surface of the filling material.

### CROSS-REFERENCE TO RELATED APPLICATIONS

This application is a continuation of International Patent Application No. PCT/CN2024/124340 filed on Oct. 12, 2024, which claims priority to Chinese Patent Application No. 202410806141.6 filed on Jun. 20, 2024. The disclosures of the above-referenced applications are hereby incorporated by reference in their entirety.

### BACKGROUND

Dynamic random access memories (DRAM) are a type of semiconductor memories. Compared to a static memory, the DRAM memory has the advantages of a simpler structure, lower manufacturing costs, and higher capacity density. With the development of the technology, the application of the DRAM memory is increasingly extensive.

A vertical channel transistor (VCT) refers to a semiconductor structure in which an active pillar extends from a substrate substantially in a direction perpendicular to the plane on which the substrate is located. In the a process of manufacturing a VCT-containing semiconductor device (for example, a DRAM), since a bit line needs to be buried under a channel, the manufacturing requires processes such as atomic layer deposition, etching, and high-temperature annealing. When materials of the semiconductor device are manufactured, slots need to be formed first in the base substrate, and then the materials are deposited in the slots, such that the manufacturing process is complex, and the formed bit line is prone to open circuit, which seriously affects the performance of the semiconductor device.

### SUMMARY

Embodiments of the present disclosure relate to the technical field of semiconductors, in particular to a semiconductor device and manufacturing method therefor, and a dynamic random access memory.

According to a first aspect of embodiments of the present disclosure, a semiconductor device is provided. The semiconductor device includes:
a substrate; a channel structure, arranged on the substrate along a first direction; a bit line, arranged between the channel structure and the substrate and electrically connected to the channel structure, and extending along a second direction; and a word line, arranged on at least one side of the channel structure and extending along a third direction, where the first direction intersects with the substrate, the second direction is parallel to the substrate, and the third direction is parallel to the substrate and intersects with the second direction; and the channel structure includes a filling material and an oxide semiconductor layer arranged on an outer surface of the filling material.

In some embodiments, a material of the oxide semiconductor layer is selected from one or more of indium gallium zinc oxide, zinc oxide, or indium zinc oxide.

In some embodiments, the filling material is silicon oxide or aluminum oxide.

In some embodiments, the word line surrounds the channel structure.

In some embodiments, the semiconductor device further includes a storage node, arranged on and electrically connected to the channel structure.

In some embodiments, the storage node includes one or more of a capacitor, a magnetoresistive memory, a phase change memory, and a ferroelectric memory.

In some embodiments, the semiconductor device further includes a first electrode, arranged on the channel structure, where for projection on the substrate along the first direction, a projection area of the first electrode is larger than a projection area of the channel structure.

In some embodiments, the semiconductor device further includes a first spacer layer, arranged between the first electrode and the word line.

In some embodiments, projections of the first spacer layer and the word line on the substrate along the first direction overlap.

In some embodiments, the semiconductor device further includes a second spacer block, where second spacer blocks are arranged at a same layer as the first electrode and spaced apart between first electrodes along the third direction.

In some embodiments, for projection on the substrate along the first direction, a projection of the second spacer block coincides with a projection of the word line in the second direction.

According to a second aspect of the embodiments of the present disclosure, a dynamic random access memory is provided. The dynamic random access memory includes:
the semiconductor device of any one of the above, a sub-word line driver, and a sense amplifier.

According to a third aspect of the embodiments of the present disclosure, a method for manufacturing a semiconductor device is provided. The method includes:
providing a substrate;
forming a bit line extending along a second direction on the substrate;
forming a channel structure on the bit line along a first direction, where the channel structure is provided with a filling material and an oxide semiconductor layer formed on an outer surface of the filling material; and
forming a word line extending along a third direction on at least one side of the channel structure,
where the first direction intersects with the substrate, the second direction is parallel to the substrate, and the third direction is parallel to the substrate and intersects with the second direction.

In some embodiments, forming the channel structure includes:
forming an intermediate layer on the substrate on which the bit line is formed, forming a hole at a corresponding position at the intermediate layer, and forming a first oxide semiconductor material layer on side walls and a bottom of the hole;
forming the filling material in the hole provided with the oxide semiconductor layer, and forming a second oxide semiconductor material layer on a surface of the filling material; and
forming the first oxide semiconductor material layer and the second oxide semiconductor material layer into the oxide semiconductor layer.

In some embodiments, the method for manufacturing a semiconductor device further includes:
forming a first spacer layer on the channel structure, and forming a first electrode on the first spacer layer.

In the embodiments of the present disclosure, the semiconductor material layer in the formed channel structure enwraps the filling material on the outer surface in the middle, such that the semiconductor material layer can be made very thin, thereby enabling the transistor to have a good on-off performance. Further, the semiconductor material layer fully enwraps the filling material, and is combined with gate-all-around, such that the effective channel has a large channel width, and a large contact area between the channel and the source/drain is ensured, which reduces the contact resistance and ensures the performance of the contact device. Further, the area of the first electrode is larger than the area of the channel structure, such that a good contact effect between the second electrode and the storage node can be ensured, the process window is improved, and the generation of poor products is reduced. Further, the first spacer layer between the first electrode and the word line can effectively prevent the interaction between the word lines.

### BRIEF DESCRIPTION OF THE DRAWINGS

FIG. 1 is a schematic view of a dynamic random access memory according to an exemplary embodiment;

FIG. 2 is a first schematic cross-sectional view of a partial structure along a word line direction and passing through a channel structure position in a certain step in manufacturing a semiconductor device according to an exemplary embodiment;

FIG. 3 is a first schematic cross-sectional view of a partial structure along a bit line direction and passing through a channel structure position in a certain step in manufacturing a semiconductor device according to an exemplary embodiment;

FIG. 4 is a second schematic cross-sectional view of a partial structure along a word line direction and passing through a channel structure position in a certain step in manufacturing a semiconductor device according to an exemplary embodiment;

FIG. 5 is a second schematic cross-sectional view of a partial structure along a bit line direction and passing through a channel structure position in a certain step in manufacturing a semiconductor device according to an exemplary embodiment;

FIG. 6 is a third schematic cross-sectional view of a partial structure along a word line direction and passing through a channel structure position in a certain step in manufacturing a semiconductor device according to an exemplary embodiment;

FIG. 7 is a third schematic cross-sectional view of a partial structure along a bit line direction and passing through a channel structure position in a certain step in manufacturing a semiconductor device according to an exemplary embodiment;

FIG. 8 is a fourth schematic cross-sectional view of a partial structure along a word line direction and passing through a channel structure position in a certain step in manufacturing a semiconductor device according to an exemplary embodiment;

FIG. 9 is a fourth schematic cross-sectional view of a partial structure along a bit line direction and passing through a channel structure position in a certain step in manufacturing a semiconductor device according to an exemplary embodiment;

FIG. 10 is a fifth schematic cross-sectional view of a partial structure along a word line direction and passing through a channel structure position in a certain step in manufacturing a semiconductor device according to an exemplary embodiment;

FIG. 11 is a fifth schematic cross-sectional view of a partial structure along a bit line direction and passing through a channel structure position in a certain step in manufacturing a semiconductor device according to an exemplary embodiment;

FIG. 12 is a sixth schematic cross-sectional view of a partial structure along a word line direction and passing through a channel structure position in a certain step in manufacturing a semiconductor device according to an exemplary embodiment;

FIG. 13 is a sixth schematic cross-sectional view of a partial structure along a bit line direction and passing through a channel structure position in a certain step in manufacturing a semiconductor device according to an exemplary embodiment;

FIG. 14 is a seventh schematic cross-sectional view of a partial structure along a word line direction and passing through a channel structure position in a certain step in manufacturing a semiconductor device according to an exemplary embodiment;

FIG. 15 is a seventh schematic cross-sectional view of a partial structure along a bit line direction and passing through a channel structure position in a certain step in manufacturing a semiconductor device according to an exemplary embodiment;

FIG. 16 is an eighth schematic cross-sectional view of a partial structure along a word line direction and passing through a channel structure position in a certain step in manufacturing a semiconductor device according to an exemplary embodiment;

FIG. 17 is an eighth schematic cross-sectional view of a partial structure along a bit line direction and passing through a channel structure position in a certain step in manufacturing a semiconductor device according to an exemplary embodiment;

FIG. 18 is a nineth schematic cross-sectional view of a partial structure along a word line direction and passing through a channel structure position in a certain step in manufacturing a semiconductor device according to an exemplary embodiment;

FIG. 19 is a nineth schematic cross-sectional view of a partial structure along a bit line direction and passing through a channel structure position in a certain step in manufacturing a semiconductor device according to an exemplary embodiment;

FIG. 20 is a tenth schematic cross-sectional view of a partial structure along a word line direction and passing through a channel structure position in a certain step in manufacturing a semiconductor device according to an exemplary embodiment;

FIG. 21 is a tenth schematic cross-sectional view of a partial structure along a bit line direction and passing through a channel structure position in a certain step in manufacturing a semiconductor device according to an exemplary embodiment;

FIG. 22 is an eleventh schematic cross-sectional view of a partial structure along a word line direction and passing through a channel structure position in a certain step in manufacturing a semiconductor device according to an exemplary embodiment;

FIG. 23 is an eleventh schematic cross-sectional view of a partial structure along a bit line direction and passing through a channel structure position in a certain step in manufacturing a semiconductor device according to an exemplary embodiment;

FIG. 24 is a twelfth schematic cross-sectional view of a partial structure along a word line direction and passing through a channel structure position in a certain step in manufacturing a semiconductor device according to an exemplary embodiment;

FIG. 25 is a twelfth schematic cross-sectional view of a partial structure along a bit line direction and passing through a channel structure position in a certain step in manufacturing a semiconductor device according to an exemplary embodiment;

FIG. 26 is a thirteenth schematic cross-sectional view of a partial structure along a word line direction and passing through a channel structure position in a certain step in manufacturing a semiconductor device according to an exemplary embodiment;

FIG. 27 is a thirteenth schematic cross-sectional view of a partial structure along a bit line direction and passing through a channel structure position in a certain step in manufacturing a semiconductor device according to an exemplary embodiment;

FIG. 28 is a fourteenth schematic cross-sectional view of a partial structure along a word line direction and passing through a channel structure position in a certain step in manufacturing a semiconductor device according to an exemplary embodiment;

FIG. 29 is a fourteenth schematic cross-sectional view of a partial structure along a bit line direction and passing through a channel structure position in a certain step in manufacturing a semiconductor device according to an exemplary embodiment; and

FIG. 30 is a schematic top view of a certain step in manufacturing a semiconductor device according to an exemplary embodiment.

### DETAILED DESCRIPTION

The technical solutions of the present disclosure will be further elaborated below with reference to the drawings and embodiments. While exemplary implementations of the present disclosure are shown in the drawings, it should be understood that the present disclosure may be implemented in various forms and should not be limited by the embodiments set forth herein. Rather, these embodiments are provided, so that the present disclosure will be more thoroughly understood and the scope of the present disclosure will be fully conveyed to those skilled in the art.

The present disclosure is more specifically described in the following paragraphs with reference to the drawings by way of example. Advantages and features of the present disclosure will become apparent from the following description and claims. It should be noted that the drawings are all in a very simplified form and not to precise scale, and are provided only for the purpose of facilitating a convenient and clear description of the embodiments of the present disclosure.

It will be appreciated that the meaning of “on”, “above”, and “over” in the present disclosure should be interpreted in the broadest manner such that “on” not only includes the meaning of “on” something with no intermediate feature or layer therebetween (i.e., directly on something) but also includes the meaning of “on” something with an intermediate feature or a layer therebetween.

In the embodiments of the present disclosure, the terms “first”, “second”, “third”, and the like are used for distinguishing similar objects and are not necessarily used for describing a particular order or sequence.

In the embodiments of the present disclosure, the term “layer” refers to a material portion that includes a region having a thickness. A layer may extend over the entirety of the underlying or overlying structure or may have an extent that is less than the extent of the underlying or overlying structure. Furthermore, a layer may be a region of a homogeneous or inhomogeneous continuous structure having a thickness less than the thickness of a continuous structure. For example, a layer may be located between a top surface and a bottom surface of a continuous structure, or a layer may be located between any pair of horizontal planes at the top surface and the bottom surface of the continuous structure. A layer may extend horizontally, perpendicularly, and/or along inclined surfaces. A layer may include a plurality of sub-layers.

It should be noted that unless conflicting, the technical solutions described in the embodiments of the present disclosure may be arbitrarily combined.

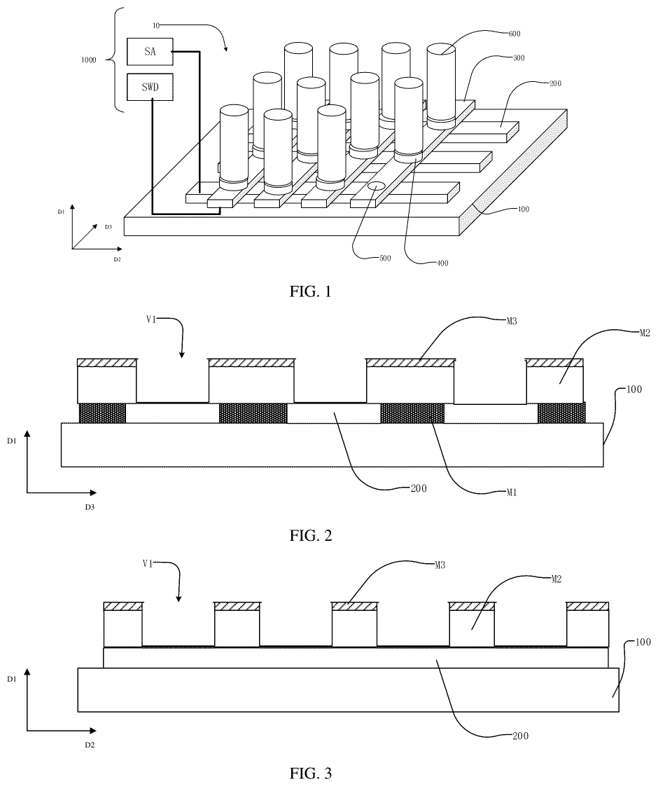

According to a first aspect of the embodiments of the present disclosure, as shown in FIG. 1, a first direction D1 intersects with a substrate 100, a second direction D2 is parallel to the substrate, and a third direction D3 is parallel to the substrate and intersects with the second direction; provided is a dynamic random access memory 1000, which includes: a semiconductor device 10, a sub-word line driver (SWD), and a sense amplifier (SA). The sub-word line driver is electrically connected to word lines in the semiconductor device for controlling the semiconductor device to operate by transmitting a drive signal. The sense amplifier is electrically connected to bit lines in the semiconductor device for contrast amplification of an electrical signal transmitted in the bit lines.

In some embodiments, the sub-word line driver is arranged in the substrate 100 and electrically connected to the word lines by wiring. Optionally, the sub-word line driver is arranged between the semiconductor device structure and the substrate; for projection on the substrate along the first direction, the sub-word line driver overlaps with the semiconductor device structure, or is separately arranged in a region outside the semiconductor device structure.

In some embodiments, the sub-word line driver is arranged on another substrate, the another substrate is connected to the semiconductor device by bonding, and the sub-word line driver is electrically connected to the word lines of the semiconductor device by bonding and wiring.

In some embodiments, the sense amplifier is arranged in the substrate 100 and electrically connected to the bit lines by wiring. Optionally, the sense amplifier is arranged between the semiconductor device structure and the substrate; for projection on the substrate along the first direction, the sense amplifier overlaps with the semiconductor device structure, or is separately arranged in a region outside the semiconductor device structure.

In some embodiments, the sense amplifier is arranged on another substrate, the another substrate is connected to the semiconductor device by bonding, and the sense amplifier is electrically connected to the bit lines of the semiconductor device by bonding and wiring.

In some embodiments, the sub-word line driver and the sense amplifier are jointly arranged on another substrate, and the sub-word line driver and the sense amplifier are electrically connected to the word lines and the bit lines of the semiconductor device by bonding and wiring, respectively. The bonding method is selected from bump bonding or hybrid bonding.

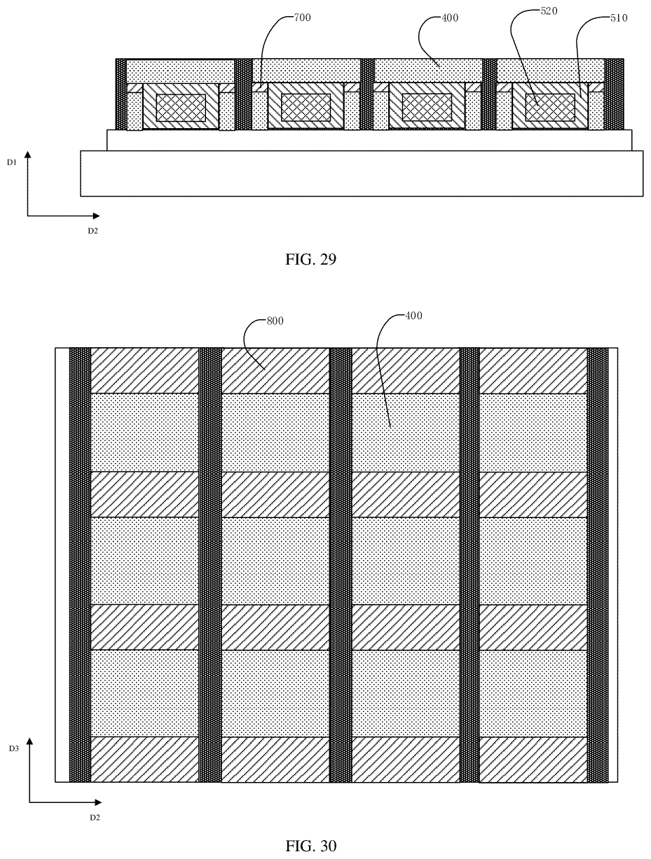

In some embodiments, as shown in FIG. 1 and FIGS. 28 to 30, the semiconductor device includes: a substrate 100, channel structures 500, bit lines 200, and word lines 300. The channel structures are distributed on the substrate in an array along a first direction; the bit lines extend along a second direction, are spaced apart between the channel structures and the substrate along a third direction, and are electrically connected to the channel structures; the word lines extend along the third direction, and are spaced apart on at least one side of the channel structures along the second direction, that is, a plurality of word lines and a plurality of bit lines cross to form a mesh-like structure, and a plurality of separate channel structures are arranged near intersections of the mesh-like structure; the word line and the channel structure form a transistor, the word line serves as a gate to control the channel structure to achieve turn-on and turn-off, and optionally, the word line is arranged on one side of the channel structure, that is, to form a single-gate transistor. Alternatively, the word line is arranged on two sides of the channel structure, which may be opposite sides or adjacent sides, that is, to form a double-gate transistor. Alternatively, the word line is arranged on three sides of the channel structure to form a tri-gate transistor. Preferably, the word line surrounds the channel structure to form a gate-all-around transistor, where the channel structure includes a filling material 520 and an oxide semiconductor layer 510 arranged on the outer surface of the filling material.

In some embodiments, the material of the oxide semiconductor layer on the outer surface of the channel structure is selected from one or more of indium gallium zinc oxide, zinc oxide, or indium zinc oxide. Preferably, the material of the oxide semiconductor layer is gallium indium zinc oxide.

In some embodiments, the material of the oxide semiconductor layer on the outer surface of the channel structure is gallium indium zinc oxide, and has other doped elements. Preferably, both ends of the channel structure along the first direction have doping elements, which may be the same or different. The doping element is selected from one or more of silicon, tin, phosphorus, arsenic, boron, copper, cadmium, aluminum, or carbon, which is used to change the conductivity of gallium indium zinc oxide.

In some embodiments, the filling material of the channel structure is selected from silicon oxide or aluminum oxide.

In some embodiments, the channel structure is in the shape of a cylinder, a cube, or a cuboid.

In some embodiments, the oxide semiconductor layer in the channel structure has a uniform thickness. Optionally, the oxide semiconductor layer has different thicknesses; the thickness of the oxide semiconductor layer, at an end away from the substrate along the first direction, is different from that on the side surface and the bottom surface.

In some embodiments, the oxide semiconductor layer in the channel structure is formed by two layers through engagement. The side surface and the bottom surface consist of one layer, and a space surrounded by the side surface and the bottom surface is filled with the filling material; another layer is arranged on the top surface and is engaged with the side surface to form a closed space, and the filling material is wrapped therein.

In some embodiments, the semiconductor device further includes storage nodes 600, arranged on and electrically connected to the channel structures. Optionally, the storage nodes are directly connected to the channel structures; optionally, the storage nodes are electrically connected to the channel structures through first electrodes 400, to transmit an electrical signal.

In some embodiments, the first electrode is arranged between the storage node and the channel structure in the first direction. Optionally, the symmetry axis of the storage node in the first direction does not coincide with the symmetry axis of the channel structure in the first direction; optionally, the symmetry axis of the storage node in the first direction coincides with the symmetry axis of the channel structure in the first direction.

In some embodiments, the first electrode is arranged on the channel structure, and a projection area of the first electrode on the substrate along the first direction is larger than a projection area of the channel structure on the substrate along the first direction. Optionally, in the second direction, the projection area of the first electrode is wider than the projection area of the channel structure, or in the third direction, the projection area of the first electrode is wider than the projection area of the channel structure. Preferably, in both the second direction and the third direction, the projection area of the first electrode is wider than the projection area of the channel structure, that is, a projection of the first electrode completely covers a projection of the channel structure.

In some embodiments, a projection of a contact point of the storage node with the first electrode on the substrate along the first direction exceeds the range of a projection of the channel structure on the substrate along the first direction.

In some embodiments, the storage node includes one or more of a capacitor, a magnetoresistive memory, a phase change memory, and a ferroelectric memory.

In some embodiments, the semiconductor device further includes first spacer layers 700, each arranged between the first electrode and the word line. In this embodiment, the length of the channel structure in the first direction is longer than the length of the word line in the first direction, that is, there is a distance between an end of the first electrode in contact with the channel structure and a region where the word line coincides with the channel structure, in which the first spacer layer is arranged.

In some embodiments, when the word line surrounds the channel structure to form a gate-all-around transistor, the first spacer layer is arranged on the word line and in contact with the channel structure to form a shape that surrounds the channel structure. That is, the channel structure penetrates through the word line and the first spacer layer.

In some embodiments, the word line is arranged on one side of the channel structure to form a single-gate transistor; or the word line is arranged on two sides of the channel structure, which may be opposite sides or adjacent sides, to form a double-gate transistor; or the word line is arranged on three sides of the channel structure to form a tri-gate transistor. Optionally, the first spacer layer is arranged on the word line, covers the upper surface of the word line, has the same shape as the word line, and also surrounds one side of the channel structure, surrounds two sides of the channel structure, or surrounds three sides of the channel structure. Optionally, the first spacer layer is arranged on the word line, the first spacer layer surrounds the channel structure, that is, a through hole is formed on the first spacer layer the channel structure is arranged in the through hole, and a projection of the first spacer layer on the substrate along the first direction covers a projection of the word line on the substrate along the first direction.

In some embodiments, when the projection area of the first electrode on the substrate along the first direction is larger than the projection area of the channel structure on the substrate along the first direction, a portion of the first electrode beyond the channel structure is arranged on the first spacer layer. Optionally, a projection area of the first spacer layer on the substrate along the first direction is larger than the projection area of the first electrode on the substrate along the first direction.

In some embodiments, projections of the first spacer layer and the word line on the substrate along the first direction overlap, that is, the first spacer layer covers the upper surface of the word line.

In some embodiments, the semiconductor device further includes second spacer blocks 800, arranged at the same layer as the first electrodes and spaced apart between the first electrodes along the third direction. That is, second spacer blocks are arranged between a plurality of first electrodes on the same word line to isolate the plurality of first electrodes from each other. Optionally, the thickness of the second spacer block is the same as the thickness of the first electrode, such that the upper surfaces of the first electrodes and the second spacer blocks on the same word line form a flat plane.

In some embodiments, in the second direction, a projection of the second spacer block on the substrate along the first direction coincides with the projection of the word line on the substrate along the first direction. That is, the width of the second spacer block is the same as the width of the word line, and the edges of the second spacer block and the word line align in the direction of the width of the word line.

In some embodiments, the first spacer layer is arranged between the first electrode and the word line, the first spacer layer covers the upper surface of the word line, and the second spacer block is arranged on the first spacer layer. In the second direction, the projection of the second spacer block on the substrate along the first direction coincides with the projection of the first spacer layer on the substrate along the first direction.

According to a second aspect of the embodiments of the present disclosure, provided is a method for manufacturing the semiconductor device described above. As shown in FIGS. 2 to 30, the method includes providing a substrate, where optionally, the substrate may be made of a semiconductor material such as monocrystalline silicon, silicon germanium, and silicon carbide, and may include other previously manufactured structures, such as transistors arranged in the substrate; and forming bit lines extending along a second direction on the substrate, where optionally, a bit line material film layer is formed on the surface of the substrate through a deposition process, a mask with a patterned bit line pattern is formed through a patterning process, and the bit line material film layer is etched through an etching process to form the bit lines 200.

In some embodiments, the patterning process includes forming a photoresist on the bit line film layer, exposing and developing the photoresist to form the photoresist with a preset pattern, and etching the bit line material film layer through the patterned photoresist to form the bit lines.

In some embodiments, the patterning process further includes forming a hard mask on the bit line material film layer, forming a photoresist on the hard mask as well as exposing and developing the photoresist to form a preset pattern, etching the hard mask through the patterned photoresist, transferring the preset pattern onto the hard mask, stripping the photoresist, and etching the bit line material film layer through the patterned hard mask to form the bit lines.

In some embodiments, with the development of semiconductor manufacturing processes, the integration level increases and the size shrinks. A first preset width and a second preset width required cannot be formed by a single patterning process, but by multiple patterning processes, for example, a lithography-etch-lithography-etch (LELE) process, a self-aligned double patterning (SADP) process, or a self-aligned quadruple patterning (SAQP) process.

In some embodiments, the deposition process of the bit line material film layer may be selected from a physical vapor deposition (PVD) method, an atomic layer deposition (ALD) method, a pulsed laser deposition (PLD) method, chemical vapor deposition (CVD), vacuum evaporation, furnace tube deposition, a damascene process, or the like.

In some embodiments, the material of the bit line material film layer may include metal, metal nitride, metal oxide, metal silicide, conductive carbon, and a combination thereof, for example, copper (Cu), aluminum (Al), tungsten (W), titanium (Ti), titanium nitride (TiN), titanium aluminum nitride (TiAlN), titanium carbonitride (TiCN), tantalum (Ta), tantalum nitride (TaN), tantalum aluminum nitride (TaAlN), tantalum carbonitride (TaCN), ruthenium (Ru), platinum (Pt), or a combination thereof, or non-metallic materials, such as polycrystalline silicon, gallium indium tin oxide, and indium tin oxide, or a combination thereof. Preferably, the material of the bit line material film layer is titanium nitride.

After forming the bit lines, a dielectric layer M1 is formed between two bit lines. Optionally, the dielectric layer is formed on the surface of the bit line at the same time to prevent the bit line from being damaged in the subsequent processes. Specifically, the method for forming the dielectric layer includes forming a dielectric layer material layer, and planarizing the dielectric layer material layer to obtain the dielectric layer.

In some embodiments, the dielectric layer material layer includes a dielectric material, such as one or more of silicon oxide, silicon nitride, silicon oxynitride, silicon oxycarbide, silicon carbonitride, and silicon oxycarbonitride.

In some embodiments, the method for forming the dielectric layer material layer is selected from a physical vapor deposition (PVD) method, an atomic layer deposition (ALD) method, a pulsed laser deposition (PLD) method, chemical vapor deposition (CVD), vacuum evaporation, furnace tube deposition, and the like.

In some embodiments, the planarization of the dielectric layer material layer may be achieved by chemical mechanical polishing (CMP). The dielectric layer material layer formed by a deposition process has an uneven surface, and the planarization is achieved through CMP by controlling the polishing duration. Optionally, when a protective layer is required to be formed on the surface of the bit line, the polishing is stopped after a preset thickness is reached, and thus the protective layer and the dielectric layer can be formed, and optionally, when only the dielectric layer is required to be formed, the polishing is stopped until the bit line is exposed.

Further, as shown in FIGS. 2 and 3, channel structures are formed on the bit lines along a first direction; specifically, sacrificial layers M2 and sacrificial layers M3 are deposited on the substrate on which the bit lines and the dielectric layers are formed, and holes V1 are formed at corresponding positions of the channel structures through a patterning process.

Optionally, the materials of the sacrificial layer M2 and the sacrificial layer M3 are selected from one or more of silicon oxide, silicon nitride, silicon oxynitride, silicon oxycarbide, silicon carbonitride, and silicon oxycarbonitride. Preferably, the sacrificial layer M2 is made of silicon oxide, and the sacrificial layer M3 is made of silicon nitride or silicon oxycarbonitride.

Optionally, the deposition method of the sacrificial layer M2 and the sacrificial layer M3 is selected from a physical vapor deposition (PVD) method, an atomic layer deposition (ALD) method, a pulsed laser deposition (PLD) method, chemical vapor deposition (CVD), or vacuum evaporation. Preferably, the deposition method of the sacrificial layer M2 and the sacrificial layer M3 is chemical vapor deposition (CVD).

Optionally, the patterning process in forming the holes V1 through the patterning process includes forming a photoresist on the sacrificial layer M3, exposing and developing the photoresist to form the photoresist with a preset pattern, and etching the sacrificial layer M2 and the sacrificial layer M3 through the patterned photoresist to form the hole V1. Similarly, a hard mask may be formed first, the hard mask is subjected to a patterning process, and the pattern in the patterned hard mask is then transferred to the sacrificial layer M2 and the sacrificial layer M3.

In some embodiments, the method for etching the sacrificial layer M2 and the sacrificial layer M3 to form the hole V1 includes anisotropic etching or isotropic etching, such as dry etching or wet etching.

In some embodiments, when the protective layer is formed on the surface of the bit line, the protective layer is removed together when forming the hole V1, such that the bit line is exposed at the bottom of the hole V1.

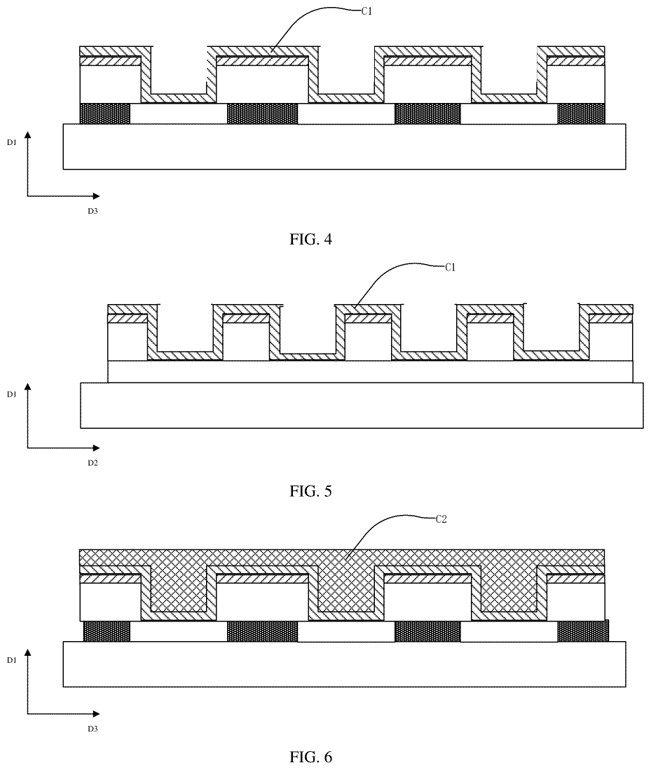

Further, as shown in FIGS. 4 and 5, a first oxide semiconductor material layer C1 is deposited on the substrate on which the holes V1 are formed, and the first oxide semiconductor material layer C1 covers the surface of the sacrificial layer M3 and the side walls and the bottom surface of the hole V1.

Optionally, the material of the first oxide semiconductor material layer C1 is selected from one or more of indium gallium zinc oxide, zinc oxide, or indium zinc oxide. Preferably, the material of the first oxide semiconductor material layer C1 is gallium indium zinc oxide.

Optionally, the deposition method of the first oxide semiconductor material layer C1 is selected from a physical vapor deposition (PVD) method, an atomic layer deposition (ALD) method, a pulsed laser deposition (PLD) method, chemical vapor deposition (CVD), vacuum evaporation, furnace tube deposition, and the like. Preferably, the deposition method of the first oxide semiconductor material layer C1 is an atomic layer deposition (ALD) method.

In some embodiments, before forming the first oxide semiconductor material layer C1, a contact layer is formed on the exposed surface of the bit line at the bottom of the hole V1; the conductivity of the contact layer is between the first oxide semiconductor material layer C1 and the bit line for reducing the contact resistance.

In some embodiments, a portion of the first oxide semiconductor material layer C1 at the bottom of the hole V1 is subjected to a doping process to form a film layer having a higher conductivity than the first oxide semiconductor material layer C1, for reducing the contact resistance of the first oxide semiconductor material layer C1 with the bit line. Optionally, the doping ion is selected from one or more of silicon, tin, phosphorus, arsenic, boron, copper, cadmium, aluminum, or carbon. Optionally, the doping method is ion implantation.

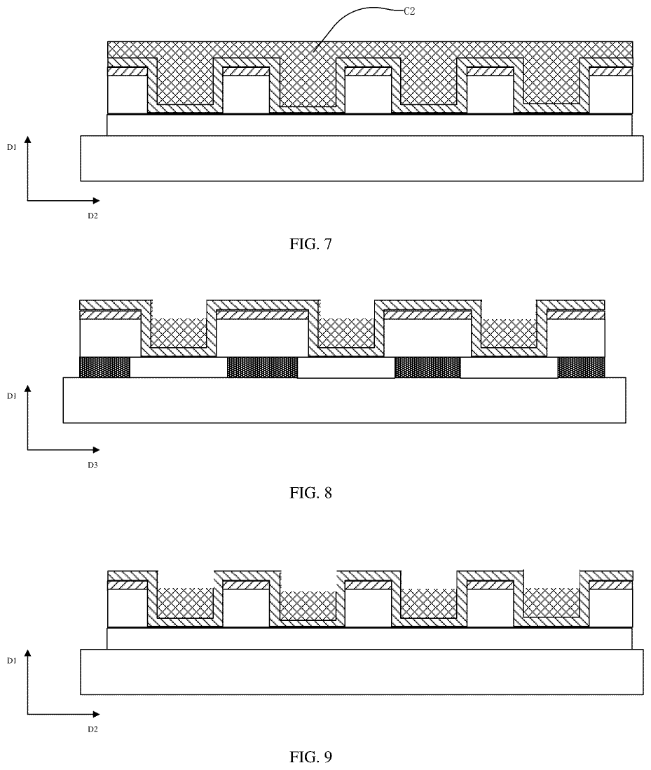

As shown in FIGS. 6 and 7, a filling material layer C2 is formed on the substrate on which the first oxide semiconductor material layer C1 is formed. Optionally, the material of the filling material layer C2 is selected from one or more of silicon oxide, aluminum oxide, silicon nitride, silicon oxynitride, silicon oxycarbide, silicon carbonitride, and silicon oxycarbonitride. Preferably, the filling material layer C2 is silicon oxide or aluminum oxide. Optionally, the deposition method of the filling material layer C2 is selected from a physical vapor deposition (PVD) method, an atomic layer deposition (ALD) method, a pulsed laser deposition (PLD) method, chemical vapor deposition (CVD), or vacuum evaporation. Preferably, the deposition method of the filling material layer C2 is to form a material layer by chemical vapor deposition (CVD), and then the material layer is planarized by using chemical mechanical polishing to form the filling material layer C2. Optionally, the filling material layer C2 is further polished to remove a portion of the filling material layer C2 on the surface of the sacrificial layer M3, thereby exposing the sacrificial layer M3.

As shown in FIGS. 8 and 9, the substrate on which the filling material layer C2 is formed is etched back, and a remaining portion of the filling material layer C2 forms the filling material in the final structure. Optionally, the upper surface of the remaining portion of the filling material layer C2 is lower than the upper surface of the sacrificial layer M3; optionally, the upper surface of the remaining portion of the filling material layer C2 is lower than the upper surface of the sacrificial layer M2. Optionally, the method for etching back the filling material layer C2 is selected from dry etching.

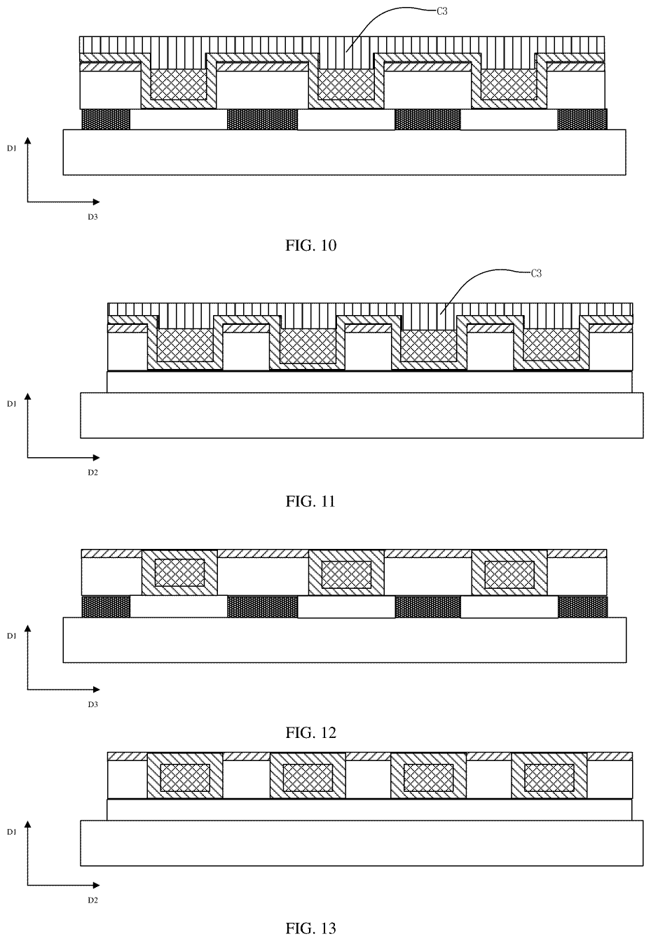

As shown in FIGS. 10 and 11, a second oxide semiconductor material layer C3 is deposited on the surface of the substrate on which the filling material layer C2 is etched back, and the second oxide semiconductor material layer C3 covers the surface of the remaining portion of the filling material layer C2 and the upper surface of the first oxide semiconductor material layer C1. Optionally, the material of the second oxide semiconductor material layer C3 is selected from one or more of indium gallium zinc oxide, zinc oxide, or indium zinc oxide. Preferably, the materials of the second oxide semiconductor material layer C3 and the first oxide semiconductor material layer C1 are both gallium indium zinc oxide.

Optionally, the deposition method of the second oxide semiconductor material layer C3 is selected from a physical vapor deposition (PVD) method, an atomic layer deposition (ALD) method, a pulsed laser deposition (PLD) method, chemical vapor deposition (CVD), vacuum evaporation, furnace tube deposition, and the like. Preferably, the deposition method of the second oxide semiconductor material layer C3 is an atomic layer deposition (ALD) method.

In some embodiments, the second oxide semiconductor material layer C3 is subjected to a doping process to form a film layer having a higher conductivity than the second oxide semiconductor material layer C3. Optionally, the doping ion is selected from one or more of silicon, tin, phosphorus, arsenic, boron, copper, cadmium, aluminum, or carbon. Optionally, the doping method is ion implantation.

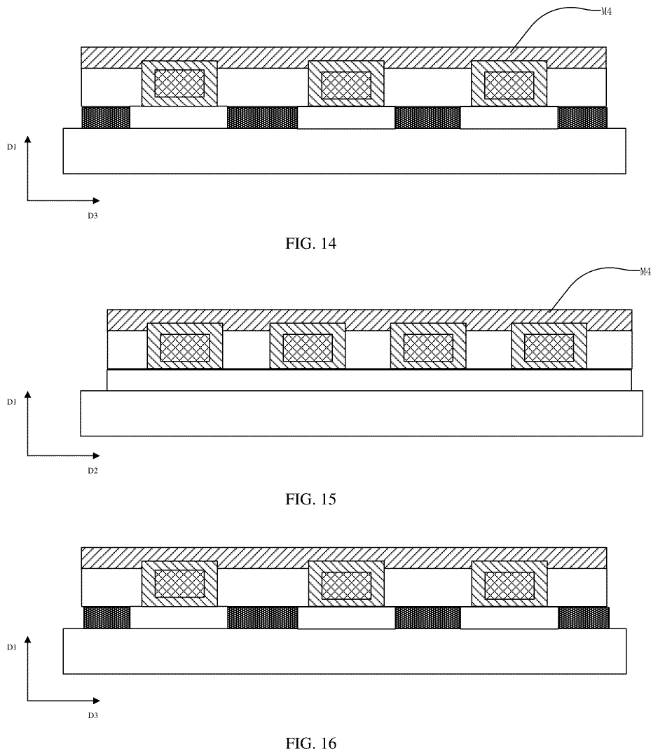

As shown in FIGS. 12 and 13, the substrate on which the second oxide semiconductor material layer C3 is formed is polished, the second oxide semiconductor material layer C3 and the first oxide semiconductor material layer C1 on the upper surface of the sacrificial layer M3 are removed in sequence, such that the sacrificial layer M3 is exposed, and a remaining portion of the second oxide semiconductor material layer C3 and a remaining portion of the first oxide semiconductor material layer C1 form oxide semiconductor layers. A space surrounded by the oxide semiconductor layer is filled with the filling material to form a complete channel structure with the filling material and the oxide semiconductor layer formed on the outer surface of the filling material. Optionally, the polishing method is chemical mechanical polishing (CMP).

In some embodiments, the upper surface of the substrate on which the complete channel structure is formed after polishing is subjected to a doping process, such that the upper surface of the channel structure has a film layer with a higher conductivity than the second oxide semiconductor material layer C3. Optionally, the doping ion is selected from one or more of silicon, tin, phosphorus, arsenic, boron, copper, cadmium, aluminum, or carbon. Optionally, the doping method is ion implantation.

As shown in FIGS. 14 and 15, a sacrificial layer M4 is deposited on the surface of the substrate on which the channel structures are formed, and the sacrificial layer M4 covers the upper surfaces of the channel structures and the sacrificial layers M3. Optionally, the material of the sacrificial layer M4 is selected from one or more of silicon oxide, silicon nitride, silicon oxynitride, silicon oxycarbide, silicon carbonitride, and silicon oxycarbonitride. Preferably, the materials of the sacrificial layer M4 and the sacrificial layer M3 are the same, such as silicon nitride or silicon oxycarbonitride. Optionally, the deposition method of the sacrificial layer M4 is selected from a physical vapor deposition (PVD) method, an atomic layer deposition (ALD) method, a pulsed laser deposition (PLD) method, chemical vapor deposition (CVD), or vacuum evaporation. Preferably, the deposition method of the sacrificial layer M4 is chemical vapor deposition (CVD).

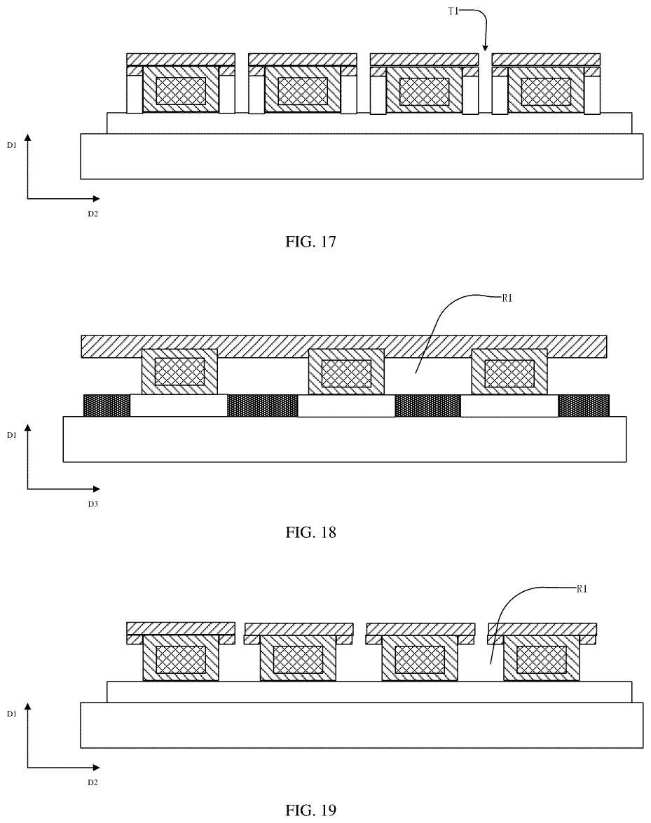

Further, as shown in FIGS. 16 and 17, trenches T1 are formed at positions between corresponding positions of word lines through a patterning process, that is, the trenches T1 are formed along the first direction, and the trenches T1 intersect with the bit lines. It will be appreciated that the patterning process is similar to the patterning process described above, and the trenches T1 are formed by photoresist patterning etching, which is not reiterated herein. Optionally, the method for etching the trenches T1 is dry etching.

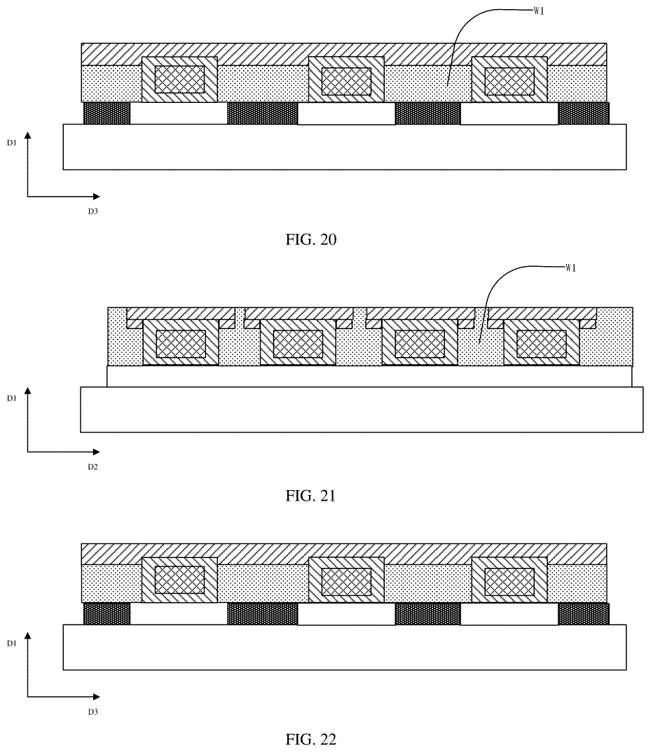

As shown in FIGS. 18 and 19, the sacrificial layers M2 are removed to form cavities R1. The cavity R1 is formed under the sacrificial layer M3 and between the channel structures. Optionally, the method for removing the sacrificial layer M2 is wet etching, and an etching solution is brought into contact with the sacrificial layer M2 through the trench T1 and reacts therewith to remove the sacrificial layer M2. Optionally, the etching rate of the etching solution on the sacrificial layer M2 is greater than the etching rate of the etching solution on the dielectric layer M1, the oxide semiconductor layer, the bit line, the sacrificial layer M3, and the sacrificial layer M4.

As shown in FIGS. 20 and 21, a word line material layer W1 is formed in the cavity R1. Optionally, forming the word line material layer W1 includes polishing after deposition. It will be appreciated that a gate insulating layer (not shown in the figures) is formed in the cavity R1 and the surface of the substrate before forming the word line material layer W1. Specifically, the material of the word line material layer W1 may include metal, metal nitride, metal oxide, metal silicide, conductive carbon, and a combination thereof, for example, copper (Cu), aluminum (Al), tungsten (W), titanium (Ti), titanium nitride (TiN), titanium aluminum nitride (TiAlN), titanium carbonitride (TiCN), tantalum (Ta), tantalum nitride (TaN), tantalum aluminum nitride (TaAlN), tantalum carbonitride (TaCN), ruthenium (Ru), platinum (Pt), or a combination thereof, or non-metallic material such as polycrystalline silicon, gallium indium tin oxide, and indium tin oxide, or a combination thereof. Preferably, the material of the word line material layer W1 is titanium nitride.

Optionally, the deposition process of the word line material layer W1 may be selected from a physical vapor deposition (PVD) method, an atomic layer deposition (ALD) method, a pulsed laser deposition (PLD) method, chemical vapor deposition (CVD), vacuum evaporation, furnace tube deposition, a damascene process, or the like. Preferably, the deposition process of the word line material layer W1 is an atomic layer deposition (ALD) method.

Optionally, the material of the gate insulating layer is formed by at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate, or includes at least one of, for example, hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate. The formation method of the gate insulating layer is an atomic layer deposition (ALD) method.

Optionally, the method for forming the word line material layer W1 by polishing is to remove excess portions of the word line material and the gate insulating material through chemical mechanical polishing (CMP) and expose the sacrificial layer M4.

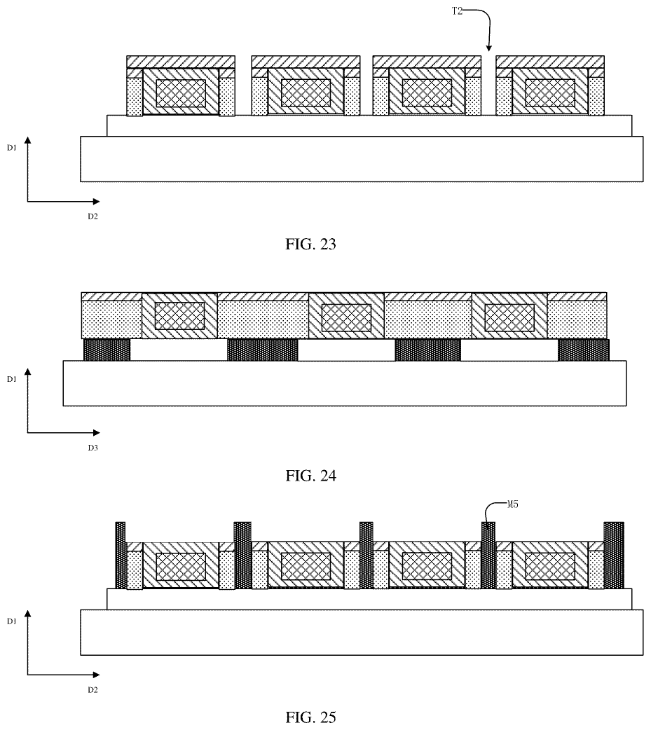

Further, as shown in FIGS. 22 and 23, trenches T2 are formed on the substrate on which the word line material layers W1 are formed, and the position of the trench T2 substantially coincides with the position of the trench T1. Specifically, anisotropic etching is performed on the substrate on which the word line material layers W1 are formed; optionally, an anisotropic etching method having a higher selectivity for the word line material layer W1 than for the sacrificial layer M4 is selected to remove a portion of the word line material layer W1 to form the trench T2. A remaining portion of the word line material layer W1 forms the word line.

Further, as shown in FIGS. 24 and 25, a dielectric layer M5 is formed in the trench T2, anisotropic etching is performed on the substrate on which the dielectric layer M5 is formed, the sacrificial layer M4 is removed and the upper surfaces of the sacrificial layer M3 and the channel structure are exposed, and a remaining portion of the sacrificial layer M3 forms a first spacer layer. Specifically, forming the dielectric layer M5 includes depositing a material layer of the dielectric layer M5, removing an excess portion of the material layer of the dielectric layer M5 by polishing, and exposing the sacrificial layer M4 to form the dielectric layer M5, and the upper surface of the dielectric layer M5 is higher than that of the first spacer layer. Optionally, the material layer of the dielectric layer M5 includes a dielectric material, such as one or more of silicon oxide, silicon nitride, silicon oxynitride, silicon oxycarbide, silicon carbonitride, and silicon oxycarbonitride.

Optionally, the method for forming the material layer of the dielectric layer M5 is selected from a physical vapor deposition (PVD) method, an atomic layer deposition (ALD) method, a pulsed laser deposition (PLD) method, chemical vapor deposition (CVD), vacuum evaporation, furnace tube deposition, and the like.

Optionally, the planarization of the material layer of the dielectric layer M5 may be achieved by chemical mechanical polishing (CMP).

Optionally, the method for removing the sacrificial layer M4 includes anisotropic etching, and it will be appreciated that, in the selected anisotropic etching method, the etching rate for the sacrificial layer M4 is greater than the etching rate for the dielectric layer M5.

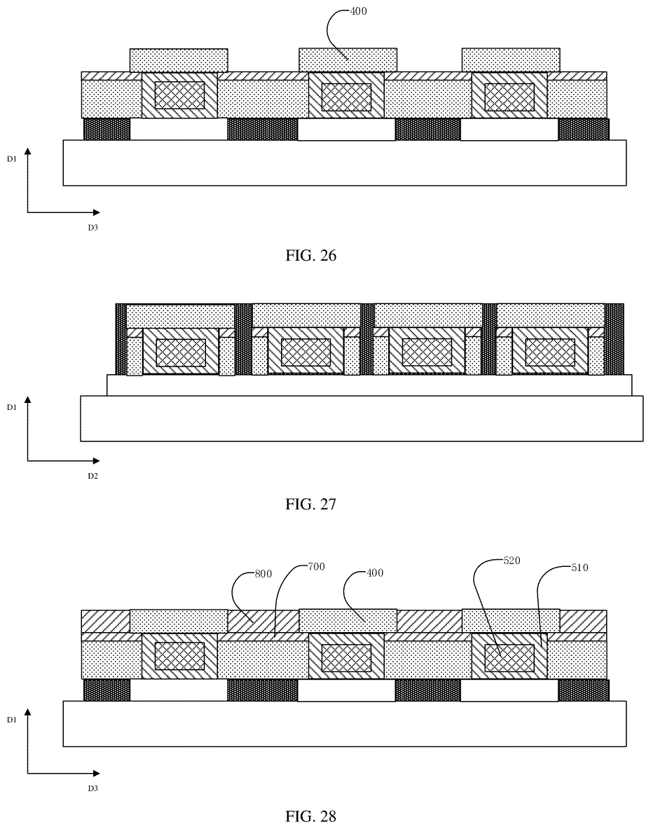

Further, as shown in FIGS. 26 and 27, first electrodes are formed on the substrate on which the first spacer layers are formed. Specifically, a first electrode material layer is first deposited on the substrate on which the first spacer layers are formed, the first electrode material layer is polished to remove an excess material to form a first electrode layer and expose the dielectric layer M5, and the first electrode layer is patterned through a patterning process and the first spacer layer is exposed to form the first electrode 400.

Optionally, the material of the first electrode material layer is selected from metal, metal nitride, metal oxide, metal silicide, conductive carbon, and a combination thereof, for example, copper (Cu), aluminum (Al), tungsten (W), titanium (Ti), titanium nitride (TiN), titanium aluminum nitride (TiAlN), titanium carbonitride (TiCN), tantalum (Ta), tantalum nitride (TaN), tantalum aluminum nitride (TaAlN), tantalum carbonitride (TaCN), ruthenium (Ru), platinum (Pt), or a combination thereof, or non-metallic materials such as polycrystalline silicon, gallium indium tin oxide, and indium tin oxide, or a combination thereof. Preferably, the material of the first electrode material layer is titanium nitride.

Optionally, the deposition process of the first electrode material layer may be selected from a physical vapor deposition (PVD) method, an atomic layer deposition (ALD) method, a pulsed laser deposition (PLD) method, chemical vapor deposition (CVD), vacuum evaporation, furnace tube deposition, a damascene process, or the like.

Optionally, the polishing of the first electrode material layer may be achieved by chemical mechanical polishing (CMP).

Optionally, the first electrode layer is patterned through a patterning process, which is similar to the patterning process described above, and etching is performed after patterning through a photoresist, which is not reiterated herein. It will be appreciated that the etching process may be selected from anisotropic etching or isotropic etching, and that the etching method, which has a greater etching rate for the first electrode material layer than for the dielectric layer M5 and the first spacer layer, is selected, so as to retain the dielectric layer M5 and the first spacer layer as much as possible.

Further, as shown in FIGS. 28 to 30, second spacer blocks are formed on the substrate on which the first electrodes are formed. Specifically, a second spacer material layer is formed on the substrate on which the first electrodes are formed, and the second spacer material layer is polished and the first electrode and the dielectric layer M5 are exposed to form the second spacer blocks 800.

Optionally, the material of the second spacer material layer is selected from one or more of silicon oxide, silicon nitride, silicon oxynitride, silicon oxycarbide, silicon carbonitride, and silicon oxycarbonitride. Preferably, the materials of the second spacer material layer and the sacrificial layer M4 are the same, such as silicon nitride or silicon oxycarbonitride. Optionally, the deposition method of the second spacer material layer is selected from a physical vapor deposition (PVD) method, an atomic layer deposition (ALD) method, a pulsed laser deposition (PLD) method, chemical vapor deposition (CVD), or vacuum evaporation. Preferably, the deposition method of the second spacer material layer is chemical vapor deposition (CVD).

Optionally, the polishing of the second spacer material layer may be achieved by chemical mechanical polishing (CMP).

In some embodiments, the channel structure with the filling material and the oxide semiconductor layer arranged on the outer surface of the filling material can control the thickness of the oxide semiconductor layer thereof by controlling the deposition processes of the first oxide semiconductor material layer and the second oxide semiconductor material layer, thereby adjusting the transistor performance of the final structure.

In some embodiments, the channel structure with the filling material and the oxide semiconductor layer arranged on the outer surface of the filling material has a larger contact area on the bottom surface and the top surface, such that it is easier to improve the yield of the product and improve the reliability of the product.

In some embodiments, the channel structure with the filling material and the oxide semiconductor layer arranged on the outer surface of the filling material makes it easier to control the thickness of the oxide semiconductor layer, and at the same time, has a large contact surface for connection to an electrode, thereby ensuring the reliability of the electrical connection while ensuring the on-off performance of the transistor.

In some embodiments, a larger first electrode formed on the channel structure can improve the fault tolerance for alignment with the storage node, expand the process window, and thus improve the product yield.

In some embodiments, the upper surface and/or the lower surface of the channel structure are/is ion-doped, such that the contact resistance can be reduced, the power consumption of the product can be reduced, and the reliability of the product can be improved.

In some embodiments, the first spacer layer is arranged between the channel structure and the first electrode, such that product reliability can be improved and electric leakage can be prevented.

In some embodiments, the second spacer block can be arranged between the first electrodes to planarize the surface of the substrate, facilitate the subsequent manufacturing processes, and meanwhile exerts an insulating function between the first electrodes to prevent electric leakage.

The various semiconductor devices shown in the specific embodiments can be used for an electronic apparatus having a memory function. The electronic apparatus may be a terminal apparatus, e.g., a mobile phone, a tablet computer, a smart bracelet, a personal computer (PC), a server, a workstation, or the like. The memory function in the electronic apparatus can be implemented by using the following memories: a dynamic random access memory (DRAM), a ferroelectric random access memory (FRAM), a phase change memory (PCM), a magnetic random access memory (MRAM), or a resistive random access memory (RRAM).

The above description is only the specific embodiments of the present disclosure, but the protection scope of the present disclosure is not limited thereto; changes or substitutions that any one skilled in the art can easily think of within the technical scope disclosed by the present disclosure shall all fall within the protection scope of the present disclosure. Therefore, the protection scope of the present disclosure shall be defined by the protection scope of the claims.

What is claimed is:

1. A semiconductor device, comprising:
a substrate;
a channel structure, arranged on the substrate along a first direction;
a bit line, arranged between the channel structure and the substrate and electrically connected to the channel structure, and extending along a second direction; and
a word line, arranged on at least one side of the channel structure and extending along a third direction,
wherein the first direction intersects with the substrate, the second direction is parallel to the substrate, and the third direction is parallel to the substrate and intersects with the second direction; and
the channel structure comprises a filling material and an oxide semiconductor layer arranged on an outer surface of the filling material.

2. The semiconductor device according to claim 1, wherein a material of the oxide semiconductor layer is selected from one or more of indium gallium zinc oxide, zinc oxide, and indium zinc oxide.

3. The semiconductor device according to claim 1, wherein the filling material is silicon oxide or aluminum oxide.

4. The semiconductor device according to claim 1, wherein the word line surrounds the channel structure.

5. The semiconductor device according to claim 1, further comprising a storage node, arranged on and electrically connected to the channel structure.

6. The semiconductor device according to claim 5, wherein the storage node comprises one or more of a capacitor, a magnetoresistive memory, a phase change memory, and a ferroelectric memory.

7. The semiconductor device according to claim 1, further comprising a first electrode, arranged on the channel structure, wherein for projection on the substrate along the first direction, a projection area of the first electrode is larger than a projection area of the channel structure.

8. The semiconductor device according to claim 7, further comprising a first spacer layer, arranged between the first electrode and the word line.

9. The semiconductor device according to claim 8, wherein projections of the first spacer layer and the word line on the substrate along the first direction overlap.

10. The semiconductor device according to claim 7, further comprising a second spacer block, wherein second spacer blocks are arranged at a same layer as the first electrode and spaced apart between first electrodes along the third direction.

11. The semiconductor device according to claim 10, wherein for projection on the substrate along the first direction, a projection of the second spacer block coincides with a projection of the word line in the second direction.

12. A dynamic random access memory, comprising:
a semiconductor device, a sub-word line driver, and a sense amplifier;
wherein the semiconductor device, comprising:
a substrate;
a channel structure, arranged on the substrate along a first direction;
a bit line, arranged between the channel structure and the substrate and electrically connected to the channel structure, and extending along a second direction; and
a word line, arranged on at least one side of the channel structure and extending along a third direction,
wherein the first direction intersects with the substrate, the second direction is parallel to the substrate, and the third direction is parallel to the substrate and intersects with the second direction;
the channel structure comprises a filling material and an oxide semiconductor layer arranged on an outer surface of the filling material;
and wherein, the sub-word line driver is electrically connected to the word line, and the sense amplifier is electrically connected to the bit line.

13. The dynamic random access memory according to claim 12,
wherein a material of the oxide semiconductor layer is selected from one or more of indium gallium zinc oxide, zinc oxide, and indium zinc oxide.

14. The dynamic random access memory according to claim 12,
wherein the semiconductor device further comprises a first electrode, arranged on the channel structure, wherein for projection on the substrate along the first direction, a projection area of the first electrode is larger than a projection area of the channel structure.

15. The dynamic random access memory according to claim 14,
wherein the semiconductor device further comprises a first spacer layer, arranged between the first electrode and the word line.

16. A method for manufacturing a semiconductor device, comprising:
providing a substrate;
forming a bit line extending along a second direction on the substrate;
forming a channel structure on the bit line along a first direction, wherein the channel structure is provided with a filling material and an oxide semiconductor layer formed on an outer surface of the filling material; and
forming a word line extending along a third direction on at least one side of the channel structure,
wherein the first direction intersects with the substrate, the second direction is parallel to the substrate, and the third direction is parallel to the substrate and intersects with the second direction.

17. The method according to claim 16, wherein forming the channel structure comprises:
forming an intermediate layer on the substrate on which the bit line is formed, forming a hole at a corresponding position at the intermediate layer, and forming a first oxide semiconductor material layer on side walls and a bottom of the hole;
forming the filling material in the hole provided with the oxide semiconductor layer, and forming a second oxide semiconductor material layer on a surface of the filling material; and
forming the first oxide semiconductor material layer and the second oxide semiconductor material layer into the oxide semiconductor layer.

18. The method according to claim 16, further comprising:
forming a first spacer layer on the channel structure, and forming a first electrode on the first spacer layer.
